(19) United States
(12) Patent Application Publication
(10) Pub. No.: US 2008/0230112 A1
(43) Pub. Date: Sep. 25, 2008

(54) Photovoltaic cells

(75) Inventors: Keith W. Barnham, Surrey (GB); Ian M. Ballard, Essex (GB); Massimo Mazzer, Parma (IT)

Correspondence Address: FOLEY AND LARDNER LLP;SUITE 500, 3000 K STREET NW, WASHINGTON, DC, 20007, US

(73) Assignee: Imperial Innovations Limited

(21) Appl. No.: 12/076,956

(22) Filed: Mar. 25, 2008

Related U.S. Application Data
(63) Continuation of application No. PCT/GB2006/003574, filed on Sep. 26, 2006.

(30) Foreign Application Priority Data
Sep. 26, 2005 (GB) GB 0519599.5

(51) Int. Cl. H01L 31/052; H01L 31/06

(52) U.S. Cl. 136/249; 136/255; 136/246

(57) ABSTRACT

A photovoltaic system includes a photovoltaic device that includes a lower photovoltaic cell fabricated from semiconductor material having a first bandgap, and having first electrical contacts for extraction of current from the lower cell; an electrically insulating layer monolithically fabricated on the lower photovoltaic cell; and an upper photovoltaic cell monolithically fabricated on the electrically insulating layer from semiconductor material having a second bandgap larger than the first bandgap, and having second electrical contacts for extraction of current from the upper cell. The photovoltaic system also includes one or more first photon sources operable to supply photons to the photovoltaic device, the photons having wavelengths in a first wavelength range associated primarily with the first bandgap. The photovoltaic system further includes one or more second photon sources operable to supply photons to the photovoltaic device, the photons having wavelengths in a second wavelength range primarily associated with the second bandgap.

### CROSS-REFERENCE TO RELATED PATENT APPLICATIONS

The present application is a Continuation of International Patent Application No. PCT/GB2006/003574 filed on Sep. 26, 2006, which claims priority to Great Britain Priority Application No. GB 0519599.5 filed on Sep. 26, 2005. The entire disclosure of International Patent Application No. PCT/GB2006/003574 and Great Britain Priority Application No. GB 0519599.5 are incorporated herein by reference in their entirety, including their specifications, drawings, claims and abstracts.

### BACKGROUND

The present invention relates to photovoltaic cells.

The generation of electricity from photovoltaic cells has been a reality for many years, but it does not yet contribute a significant fraction of overall electricity generation. A reason for this is that electricity generated by photovoltaic cells is more expensive than conventionally generated electricity, mainly because the cost of individual photovoltaic cells is still high. There are two approaches that can be used to reduce costs. One option is to manufacture the cells from cheaper materials, but this generally leads to a lower conversion efficiency. Alternatively, cell efficiency may be increased. High efficiency cells can be used in solar concentrators where light from the sun is collected over a large area and concentrated onto a smaller area photovoltaic cell, or in thermophotovoltaic systems where the cells are illuminated by high intensity light generated from a hot source such is as created by the combustion of fuel.

Photovoltaic cells may be made from a single bandgap semiconductor material (such as silicon) (see W. P. Mulligan et al., “A flat-plate concentrator: Micro-concentrator design overview,” in Conference Record of the Twenty-Eighth IEEE Photovoltaic Specialists Conference—2000, IEEE Photovoltaic Specialists Conference, 2000, pp. 1495-1497), but even ideal material of this type gives only a limited conversion efficiency when converting light from a wide spectral range, such as solar illumination. One technique for increasing efficiency is to use multiple cells with different bandgaps to convert different parts of the illuminating solar spectrum, with each cell optimized for the restricted illuminating spectrum that it receives. This approach increases overall conversion efficiency at the expense of increased complexity. For example, the required spectral splitting can be achieved using optics to deflect the correct part of the spectrum to the relevant cell, but this is difficult to implement, especially with concentration of the light.

An alternative technique is to stack two or more different cells in order of bandgap, with the highest bandgap cell at the illuminated face of the structure. Unabsorbed light from each cell penetrates further into the stack to be converted by the optimum cell. Such a device is called a tandem cell. The cells that make up the tandem can be grown individually and stacked together in a mechanical fashion (see Terao, A. et al., “Mechanically Stacked Cells for Flat-Plate Micro-Concentrators,” in Proceedings of 19th European Photovoltaic Solar Energy Conference, 2004: Paris, France, p. 2285-2288), or the entire device may be grown monolithically using any of the known growth techniques (for example metal-organic chemical vapour deposition (MOCVD), molecular beam epitaxy (MBE), and liquid-phase epitaxy (LPE)) (see Japanese Patent Publication No. JP 2002368238 and T. Nagashima et al., “Carrier Recombination of Germanium Back-Contacted type bottom cells for three-terminal Tandem Solar Cells,” in Proceedings of the 17th European Photovoltaic Solar Energy Conference. 2001: Munich, Germany, p. 2203-2206). Mechanically stacked cells have a number of engineering and commercial disadvantages. Each cell in a mechanical stack requires its own substrate for growth, which increases the overall cost. Additionally, complex engineering is required to provide good electrical connection to the stack, good thermal connections between the cells to dissipate heat which would otherwise reduce efficiency, and good optical connection between the cells. Overall, such cells tend to suffer from poor efficiency and poor reliability. For these reasons, monolithic stacks in which the cells are grown one on another on a common substrate are preferred. In a monolithic cell structure there is a requirement to create an ohmic electrical connection between the different bandgap regions. This is achieved by the use of tunnel diodes between the cells so that the overall structure has only two electrical connections. The individual cells within the structure are connected in series so that the current through any cell is the same for all cells.. This design leads to a current constraint whereby each cell must generate the same current for efficient operation. It is possible to design and optimise a structure for a particular spectrum (e.g. AM 1.5D), but when used in practice, such as in a terrestrial solar concentrator system, the spectrum will change throughout the day and throughout the year. This means that for much of the time the individual cells will not be current matched and the device efficiency will be reduced from the optimum value recorded when under the designed illumination spectrum. Furthermore, temperature variation is significant in a concentrator system so that the cell bandgap variation will mean that the efficiency is reduced from the current matched optimum.

### SUMMARY

An exemplary embodiment relates to a photovoltaic system that includes a photovoltaic device that includes a lower photovoltaic cell fabricated from semiconductor material having a first bandgap, and having first electrical contacts for extraction of current from the lower cell; an electrically insulating layer monolithically fabricated on the lower photovoltaic cell; and an upper photovoltaic cell monolithically fabricated on the electrically insulating layer from semiconductor material having a second bandgap larger than the first bandgap, and having second electrical contacts for extraction of current from the upper cell. The photovoltaic system also includes one or more first photon sources operable to supply photons to the photovoltaic device, the photons having wavelengths in a first wavelength range associated primarily with the first bandgap. The photovoltaic system further includes one or more second photon sources operable to supply photons to the photovoltaic device, the photons having wavelengths in a second wavelength range primarily associated with the second bandgap.

Another exemplary embodiment relates to a method of generating electricity via the photovoltaic effect that includes providing a photovoltaic device that includes a lower photovoltaic cell fabricated from semiconductor material having a first bandgap, and having first electrical contacts for extraction of current from the lower cell; an electrically insulating layer monolithically fabricated on the lower photovoltaic cell; and an upper photovoltaic cell monolithically fabricated on the electrically insulating layer from semiconductor material having a second bandgap larger than the first bandgap, and having second electrical contacts for extraction of current from the upper cell. The method also includes exposing the device to photons supplied by one or more first photon sources, the photons having wavelengths in a first wavelength range associated primarily with the first bandgap, and extracting current from at least the lower photovoltaic cell. The method further includes exposing the device to photons supplied by one or more second photon sources, the photons having wavelengths in a second wavelength range associated primarily with the second bandgap, and extracting current from at least the upper photovoltaic cell.

### BRIEF DESCRIPTION OF THE DRAWINGS

FIG. 1 shows a schematic representation of a photovoltaic cell according to the prior art.

FIG. 2 shows a schematic representation of a photovoltaic device for use in embodiments of the present invention; FIGS. 3A, 3B and 3C show graphs of conversion efficiencies available from photovoltaic devices for use in accordance with embodiments of the invention.

FIG. 4 shows a schematic representation of a photovoltaic device incorporating a MIMS arrangement for use in further embodiments of the invention.

FIG. 5 shows a schematic representation of a photovoltaic device incorporating a tunnel junction for use in yet further embodiments of the invention.

FIGS. 6, 7, 8 and 9 show schematic representations of systems incorporating photovoltaic devices in accordance with various embodiments of the invention.

### DETAILED DESCRIPTION

According to an exemplary embodiment, a photovoltaic device comprises an upper cell and a lower cell separated by an electrically insulating layer. The cells and the layers are fabricated as a single monolithic structure, and separate electrical contacts are provided for the upper and lower cells to allow independent extraction of current from each cell. The upper cell has a larger bandgap than the lower cell so that incident low energy photons unabsorbed and unconverted by the upper cell can propagate through to the lower cell for conversion. The two bandgaps can be selected to accommodate spectral ranges of interest. The device is incorporated into a system including two sources of photons with different wavelength ranges associated with the bandgaps of the two cells, such that each cell can convert photons from one source. One source may be the sun and the other may be a local photon source such as a thermal source. Alternatively, both photon sources may be local sources. Operation of the device can be further optimized and extended by configuring the upper cell as a tandem cell or in a MIMS arrangement, or both.

According to a particular exemplary embodiment, a photovoltaic system comprises a photovoltaic device that comprises (a) a lower photovoltaic cell fabricated from semiconductor material having a first bandgap, and having first electrical contacts for extraction of current from the lower cell; (b) an electrically insulating layer monolithically fabricated on the lower photovoltaic cell; and (c) an upper photovoltaic cell monolithically fabricated on the electrically insulating layer from semiconductor material having a second bandgap larger than the first bandgap, and having second electrical contacts for extraction of current from the upper cell. The photovoltaic system also comprises one or more first photon sources operable to supply photons to the photovoltaic device, the photons having wavelengths in a first wavelength range associated primarily with the first bandgap. The photovoltaic system further comprises one or more second photon sources operable to supply photons to the photovoltaic device, the photons having wavelengths in a second wavelength range associated primarily with the second bandgap.

A reliable and proven monolithic device technique is used to provide a photovoltaic device that is operable over two separate wavelength regimes, but which removes the requirement for current matching between individual cells and does not require any tunnel junctions. Thus, many disadvantages of prior art tandem and stacked multi-cell photovoltaic devices are obviated. The electrical isolation of the upper and lower cells allows each to be designed and operated with optimum efficiency for wholly different spectral ranges. Each cell can be operated completely independently of the other, so that each can be optimized for maximum photon conversion efficiency of its associated photon source and can operate efficiently regardless of operation of the other cell and/or source. Thus the invention offers a hybrid system for independent and optimal conversion of photons from different sources in a single compact device. The bandgaps of the two cells can be selected to tailor the spectral range of the system as required, thus expanding the operating range over that of a single cell device but without the current limitations of a standard tandem device. Two wholly separate photon sources operating at different wavelengths can be coupled with a single photovoltaic device to provide highly efficient electricity generation by mixing and matching available optical power.

In some embodiments, one of the first and second photon sources is a photon collecting assembly arranged to collect photons from the sun or a modified solar spectrum and deliver them to the photovoltaic device, and the other of the first and second photon sources is a local photon source. For example, the local photon source may be a thermal photon source, a monochromatic photon source or a luminescent photon source. In this way, the system can be used to generate electricity around the clock, by generating power from solar photons during the day and switching to the local photon source at night. An advantage of this over a conventional solar cell is that costs are reduced because the overall cost of the cell is split between the two operating regimes while still maintaining high efficiency in both modes. A practical arrangement for this is to use the upper cell as the solar cell, in which case the second photon source is the photon collecting assembly, and the upper photovoltaic cell is optimized for photovoltaic conversion of photons emitted by the sun, or photons emitted by the sun and spectrally modified in some way such as attenuation at short wavelength by a luminescent source or modification by a high bandgap photovoltaic cell. Also, the lower photovoltaic cell may be optimized for photovoltaic conversion of photons emitted by the local photon source. However, in the event that a suitable large bandgap material is available for the upper cell together with a photon source generating short wavelength photons for conversion in the upper cell, the lower cell could be used for solar conversion.

In other embodiments, the first photon source may be a local photon source, and the second photon source may also be a local photon source, such as a thermal photon source, a monochromatic photon source or a luminescent photon source. Any combination of local sources may be used as desired, for example to exploit particularly efficient semiconductor materials with specific bandgaps or absorption thresholds. This allows very precise tailoring of the device for efficient electricity generation.

Alternatively, the first photon source may be a photon collecting assembly arranged to collect photons from the sun or a modified solar spectrum and deliver them to the photovoltaic device, and the second photon source may be a photon collecting assembly arranged to collect photons from the sun or a modified solar spectrum and deliver them to the photovoltaic device. This arrangement can make highly efficient use of the solar spectrum by supplying the photons in an effective way for conversion in the device as a whole, depending on the bandgaps of the two individual cells. The bandgaps can be chosen to complement one another to cover as much of the solar spectrum as possible. The solar photons may be directed to the most appropriate cell according to their wavelength.

In a further embodiment, the first photon source and the second photon source may be a common local photon source operable to supply photons in the first wavelength range and the second wavelength range. The two cells can be selected such that their bandgaps together cover as much of the output spectrum of the local source as possible, so that as much as possible of the source output can be utilized. This can be useful to achieve high conversion efficiencies from a relatively broadband local source, for example.

In any of these configurations, the photons from the first photon source can be supplied to the lower photovoltaic cell via the upper photovoltaic cell and the insulating layer, and the photons from the second photon source can be supplied directly to the upper photovoltaic cell. In other words, the top surface of the device is exposed to the outputs of both photon sources, with the longer wavelength photons from the first source passing through the upper cell unabsorbed, to be absorbed in the lower cell for electricity generation. This arrangement is useful in that only one surface of the photovoltaic device need be optimized for photon exposure, for example by anti-reflection coating and situating of electrical contacts and housing outside the intended exposure area. To facilitate this arrangement, the system may further comprise a positioning mechanism operable to configure the photovoltaic system between a first configuration in which the upper photovoltaic cell can receive photons supplied by the first photon source, and a second configuration in which the upper photovoltaic cell is exposed to photons supplied by the second photon source.

Regarding the photoelectric device, many combinations of semiconductor materials and p-n junction structures can be used for the upper and lower cells, offering a wide functionality. For example, the lower photovoltaic cell may be fabricated from an indirect bandgap semiconductor material, such as silicon, germanium or silicon-germanium alloys.

Advantageously, the first electrical contacts are located on a lower side of the lower photovoltaic cell, opposite to the electrically insulating layer.

According to an exemplary embodiment, the electrically insulating layer has an absorption threshold that is larger than the bandgap of the semiconductor material from which the upper cell is fabricated. This allows any photons of a wavelength too long to be converted by the upper cell to pass without absorption through the electrically insulating layer and into the lower cell for conversion.

In some embodiments, the upper photovoltaic cell may comprise two or more photovoltaic subcells electrically connected in series and arranged adjacent to one another in the plane of the upper cell to form a monolithic integrated module structure (MIMS). This allows the advantages of MIMS configurations to be combined with the advantages of the present invention. The arrangement is facilitated by the monolithically-grown electrically insulating layer. Further, each photovoltaic subcell may comprise two or more p-n junction structures arranged one above another and fabricated from semiconductor materials of different bandgap, and electrically connected in series by one or more tunnel junctions to form a tandem photovoltaic subcell. Alternatively the two cells of the tandem may be independently contacted to the top of the cell. The advantages of tandem cells may thereby also be incorporated. Alternatively, the advantages of tandem cells may be exploited without the MIMS configuration. For example, the upper photovoltaic cell may comprise two or more p-n junction structures arranged one above another and fabricated from semiconductor 5. materials of different bandgap, and electrically connected in series by one or more tunnel junctions to form a tandem photovoltaic cell. Again, alternatively the two cells of the tandem may be independently contacted to the top of the cell.

Efficiency may be improved by configuring the device such that the upper cell comprises one or more Bragg reflectors and/or photonic cavity structures to increase 0 photon recycling in the upper cell. Alternatively or additionally, one or more surfaces of the lower cell may be passivated to reduce surface recombination of charge carriers.

While the total number of electrical contacts may be selected according to the junction configurations used for the upper and lower cells, an attractively simple arrangement is a four-terminal device. In accordance with this, the first electrical 5 contacts comprise a first single pair of electrical contacts, and the second electrical contacts comprise a second single pair of electrical contacts.

According to an exemplary embodiment, a method of generating electricity via the photovoltaic effect includes providing a photovoltaic device that comprises (a) a lower photovoltaic cell fabricated from semiconductor material having a first bandgap, and having first electrical contacts for extraction of current from the lower cell; (b) an electrically insulating layer monolithically fabricated on the lower photovoltaic cell; and (c) an upper photovoltaic cell monolithically fabricated on the electrically insulating layer from semiconductor material having a second bandgap larger than the first bandgap, and having second electrical contacts for extraction of 5 current from the upper cell. The method also includes exposing the device to photons supplied by one or more first photon sources, the photons having wavelengths in a first wavelength range associated primarily with the first bandgap, and extracting current from at least the lower photovoltaic cell. The method further includes exposing the device to photons supplied by one or more second photon sources, the photons having wavelengths in a second wavelength range associated primarily with the second bandgap, and extracting current from at least the upper photovoltaic cell.

One of the first and second photon sources may be the sun or a modified solar spectrum and the other of the first and second photon sources may be a local photon source. For example, the second photon source may be the sun or a modified solar spectrum, and the upper photovoltaic cell may be optimized for photovoltaic conversion of photons emitted by the sun or the modified solar spectrum. Hence, the method may comprise exposing the device to photons supplied by the sun during daylight hours, and exposing the device to photons supplied by the local photon source outside daylight hours.

Alternatively, the first photon source may be a local photon source, and the second photon source may also be a local photon source. The method may comprise exposing the device to photons supplied by the first photon source during one or more first time periods, and exposing the device to photons supplied by the second photon source during one or more second time periods different from the one or more first time periods. Alternatively, the method may comprise exposing the device to photons supplied by the first photon source simultaneously with exposing the device to photons supplied by the second photon source.

Exposing the device to photons supplied by the first photon source and exposing the device to photons supplied by the second photon source may each comprise exposing the upper photovoltaic cell to the photons. Further, exposing the device to photons supplied by the first photon source may comprise arranging the device in a first configuration in which the upper photovoltaic cell is exposed to photons from the first photon source, and exposing the device to photons supplied by the second photon source may comprise arranging the device in a second configuration in which the upper photovoltaic cell is exposed to photons from the second photon source. Alternatively, exposing the device to photons supplied by a first photon source may comprise exposing the lower photovoltaic cell to photons from the first photon source, and exposing the device to photons supplied by a second photon source may comprise exposing the upper photovoltaic cell to photons from the second photon source.

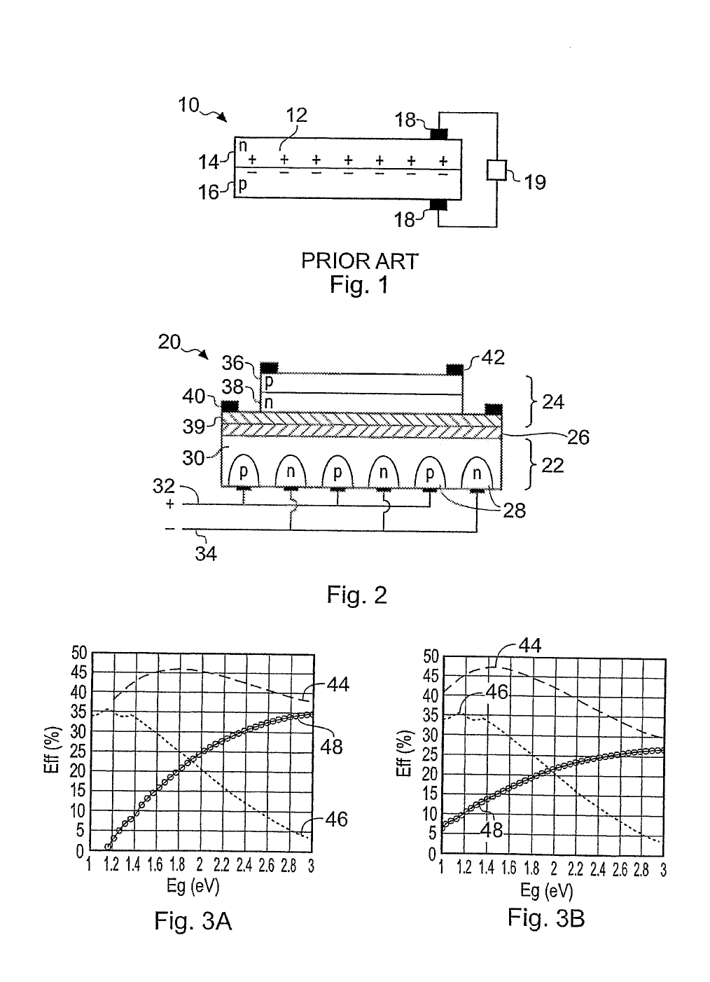

FIG. 1 shows a schematic representation of a simple photovoltaic cell, such as a solar cell, according to the prior art. The cell 10 comprises a portion 12 of a semiconductor material such as silicon which contains a p-n junction, that is, the semiconductor portion 12 comprises a first part 14 that is n-type semiconductor arranged adjacent to a second part 16 that is p-type semiconductor. This arrangement forms an electric field across the junction, arising from ionized donors on one side and ionized acceptors on the other side. Electrical contacts 18 are provided on each side of the cell 10, and hence on each side of the junction.

When a photon of electromagnetic radiation with an appropriate energy (i.e. in an appropriate wavelength range) is incident on the cell 10 and is absorbed by the semiconductor, its energy transfers an electron from the valence band of the semiconductor to the conduction band, thus generating an electron-hole pair. The electric field causes the electron to move to the n-type side of the junction and the hole to move to the p-type side of the junction. Thus there is movement of charge. If an external current path is provided, by connecting conducting wires to the electrical contacts 18, electrons will flow as current along the path to the p-type side to combine with the holes that have moved there under the influence of the electric field. Thus, the energy of the photons is converted to electrical current, which can be utilized by a load 19 connected to the external current path. This is the photovoltaic effect. In the event that the photons originate from solar emission, i.e. sunlight, the photovoltaic cell 10 is a solar cell, operable to generate electrical power from the sun's energy.

However, a cell of the type shown in FIG. 1, fabricated from a single bandgap semiconductor material, has a limited conversion efficiency when converting photons with a wide range of wavelengths, such as solar illumination. For example, silicon, while an excellent semiconductor material, has poor absorption of near- infrared and visible light.

The present invention seeks to address this issue by proposing a system incorporating a photovoltaic device that comprises upper and lower photovoltaic cells configured for independent operation by having dedicated electrical contacts and being separated by an insulating layer. The device can therefore be utilized in conjunction with a variety of sources of photons, being illuminated by one or both at different times.

FIG. 2 shows a schematic representation of a first embodiment of such a photovoltaic device. The device 20 comprises a lower photovoltaic cell 22, an upper photovoltaic cell 24 and an electrically insulating layer 26 disposed between the two cells. The lower cell 22 has an p-n junction structure defined by a series of regions 28 of alternating p-type and n-type semiconductor material adjacent to the lower or rear surface of the lower cell 22 and formed in a larger region or substrate 30 of intrinsic or lightly doped semiconductor material. Each region 28 has an electrical contact. The p- type regions are electrically connected together to give a positive electrical terminal or connection 32 and the n-type regions are electrically connected together to give a negative electrical terminal or connection 34, by which electrical current can be extracted from the lower cell 22.

The upper cell 24 has a p-n junction structure similar to that of FIG. 1, comprising a layer 36 of p-type material overlying a layer 38 of n-type material. Electrical connection for extraction of current from the upper cell 24 is provided by electrical contacts 42 on the upper surface of the upper cell 24, and a transverse conducting layer 39 underneath the upper cell 24 and extending past the edges of the upper cell 24 to provide space for further electrical contacts 40. The transverse conducting layer 39 is formed over the insulating layer 26.

The upper cell 24 is made from a semiconductor material having an effective bandgap which is larger than the effective bandgap of the semiconductor material from which the lower cell 22 is made. Thus, incident photons having a wavelength too long to be absorbed by the material of the upper cell 24 pass through to the lower cell 22, where they are absorbed by the lower bandgap material. Thus, for incident illumination with spectral ranges covering both bandgaps, the spectral range and conversion efficiency for the photovoltaic device are increased beyond the range and efficiency for either of the cells alone.

An electrically insulating layer 26 is arranged between the upper cell 24 and the lower cell 22, i.e. between the lower surface of the upper cell 24 and the upper surface of the lower cell 22. Thus, the upper and lower cells operate independently, with no current flow between the two.

The device 20 is a monolithic structure, fabricated by growing or depositing layers in sequence directly on the layer below. Any suitable semiconductor growth/deposition technique or techniques can be used, such as for example metal-organic chemical vapor deposition (MOCVD), molecular beam epitaxy (MBE), or liquid-phase epitaxy (LPE). Diffusion, ion implantation, or other processes can be used to dope the substrate layers to form the p-type and n-type regions, either before or after the addition of subsequent layers. Thus, a device can be made by taking a substrate of material suitable for the lower cell; fabricating the lower cell from the substrate by depositing or growing layers and/or by forming doped regions; forming the insulating layer on a surface of the lower cell or its substrate; and fabricating the upper cell on the insulating layer, again by forming a layer or layers and/or doping the layer(s). Alternatively, any doping to form the lower cell can be performed together with that for the upper cell, after the growth or deposition of the various layers. Also, the electrical contacts for the upper and lower cell are formed, either in a single stage, or in different stages throughout the fabrication process.

The described structure offers many advantages over previously proposed extended spectral range devices such as stacked cells and tandem cells. For example:
Electrical isolation of the upper and lower cells allows the operating conditions of each cell to be optimized, giving improved conversion efficiency. This is not possible in a conventional tandem cell, in which the worst performing cell will act to limit the other cell.
The electrical isolation, and associated dedicated electrical connections for each cell, frees the device from the current constraints of tandem cells, in which the individual cell or junction regions are connected in series using tunnel diodes or junctions to give a total current limited to that of the cell with the lowest current. The device thus has an improved dependence of efficiency on spectral and temperature variations.
During the expected twenty year or longer lifetime of the device, one cell may degrade at a different rate from the other. The independent electrical operation of the cells renders this degradation less important than for series-connected cells since each cell can give continuous optimum conversion without being affected by the other.
Compared to stacked cells, the monolithic structure provides good optical connection between the upper and lower cells. For embodiments subject to radiative recombination in the upper cell, such as if the upper cell comprises a strain-balanced quantum well solar cell (see U.S. patent application Ser. No. 10/841,843 (Publication No. 2005/0247339)), the generated photons can thus be effectively coupled into the lower cell, giving an increased overall efficiency.
Monolithically grown but independent cells can be more easily characterized than a conventional tandem cell, in which there is a requirement to light-bias one cell to allow characterization of the other. In the present case, characteristics such as the dark IV, light IV and quantum efficiency can be measured directly.
The monolithic structure ensures a good thermal connection throughout the various parts of the device so that excess heat, which would otherwise reduce the conversion efficiency, can be effectively coupled to a heat sink.
A high yield of devices should be achieved during manufacture because the design is more tolerant to faults than designs incorporating multiple tunnel junctions. In a conventional tandem, there is much greater variation in efficiency with fabrication-induced variation in the bandgap of the upper cell than for a device of the present invention.

FIG. 3A, 3B and 3C show graphs of potential efficiencies available from a device according to the present invention. FIG. 3A relates to a device with a silicon lower cell, while FIG. 3B relates to a device with a germanium lower cell, each at a concentration level of 500 times. In each case, the efficiencies Eff of the upper cell alone (lines 46) and the lower cell alone (lines 48) are compared with the efficiency of the cells combined in a device according to the invention (lines 44) for various upper cell bandgaps Eg. These graphs illustrate how the efficiency is increased over that of either of the individual cells for any given upper cell bandgap.

FIG. 3C also plots the variation of efficiency with the upper cell bandgap. In this case, the lower cell efficiency (line 100), the upper cell efficiency (line 102), and the total efficiency (line 104) for a four terminal device according to an embodiment of the invention are compared with the efficiency of an ideal two terminal conventional tandem cell (line 108). The bandgap of GaAs is also shown (line 106). It can be seen that the efficiency of the four terminal device is much less sensitive to the bandgap of the top cell than is the efficiency of the tandem cell. As the bandgap is strongly dependent on temperature, the efficiency of the four terminal device will be much less sensitive to the temperature variations that occur in solar concentrator systems than the conventional tandem cell.

It is to be emphasized that the device 20 of FIG. 2 is merely one example of a photovoltaic device according to the present invention. Each of the upper and lower photovoltaic cells can have any photovoltaic cell structure that allows the cell to be operated independently from the other cell as regards extraction of current. The p-type and n-type regions can have any shape and arrangement that forms a workable junction (possibly in conjunction with layers or regions of undoped, intrinsic or lightly doped semiconductor material) and which allows separate electrical contacts to be provided for each cell. Further examples are discussed below; these are exemplary and not limiting. Also, a range of different semiconductor materials can be used for the two cells, so that the properties of the device can be tailored to different applications. In some embodiments the lower cell may be formed from indirect bandgap material, such as silicon, germanium or a silicon-germanium combination or alloy.

For example, the upper cell may be a GaAs-based cell (such as a strain-balanced quantum well solar cell or a GaInP/GaAs tandem cell), and the lower cell may be formed from a germanium substrate. This combination of materials is particularly advantageous. The bandgap of germanium is well-suited for extending the spectral range and hence efficiency of the GaAs upper cell. Also, the lattice constant of GaAs is similar to that of germanium so that the upper cell can be successfully grown on the lower cell by epitaxy, and in any case a germanium substrate is much less expensive than a GaAs substrate.

The use of germanium for the lower cell allows that cell to be largely optimized without the expensive and time-consuming stage of metal organic vapor phase epitaxy (MOVPE) overgrowth often used for a single cell germanium device. This offers reduced overall development time and cost.

Regarding the insulating layer, this is monolithically grown on the upper surface of the lower cell (where the lower cell may comprise a previously grown cell structure, or a simple semiconductor substrate into which junction regions are later formed by a technique such as diffusion) by any suitable fabrication method, such as epitaxy. If the device is used in an arrangement in which the photons for both cells are delivered via the upper cell, a required property for the insulating layer is that at least some of the photons that are not absorbed by the upper cell are able to travel through the insulating layer into the lower cell. Thus, according to an exemplary embodiment, the insulating layer has a higher effective bandgap or absorption threshold than the upper cell (and also therefore than the lower cell) to reduce absorption in the layer. This will also allow the layer to act as a minority carrier mirror, keeping the charge carriers within their originating cells. AlGaAs and GaInP alloys which are lattice matched to GaAs and of higher bandgap than GaAs are examples of materials suitable for the insulating layer. However, other materials that offer the required functionality may also be used.

The electrical contacts on the front and rear surfaces of the device can be fabricated using any suitable technique, such as evaporation, laser grooved buried contact metallization, or screen printing. Many such techniques are well-established in the electronics industry. As described above, the electrical contacts for the upper cell are provided on the upper or front surface of the device (and of the upper cell), and the electrical contacts for the lower cell are provided on the rear or lower surface of the device (and of the lower cell). However, embodiments in which the electrical contacts are otherwise placed are not excluded. The separate contacts for the two cells allow each to be operated independently, which offers advantages in the maximum efficiency available and in how the efficiency changes with varying spectral conditions. Additionally, the electrical independence of each cell offers more flexibility in connecting multiple devices together, for example to form a module for use in a solar panel or solar concentrator. In any embodiment, however, the minimum requirement is for two pairs of electrical contacts (four in total), a single pair for the upper cell and a single pair for the lower cell.

The lower cell may therefore be a rear-contacted cell, such as shown in FIG. 2. Such cells were developed in the 1970s for use in thermophotovoltaics (see E. Kittle et al., “Performance of Germanium PIN-Photovoltaic cells at high incident Radiation Intensity,” in Proceedings of the 11th Photovoltaic Specialist Conference, 1975, pp. 424-430), in which light from a hot body is converted into electricity. To achieve high efficiency, the light source was coated in a selective emitter such that the illuminating spectrum incident on the cell was narrow-band. However, the structure was not useful for solar applications where much of the current would be generated close to the lossy front surface, so later work optimized similar structures for use with solar illumination (see S.-Y. Chiang et al., “Thin Tandem Junction Photovoltaic,” in Conference Record, 13th IEEE Photovoltaic Specialist Conference, 1978, New York, IEEE pp. 1290-1293) by using a highly doped front surface to reduce losses. Rear-contacted germanium cells have been suggested more recently (see Japanese Patent Publication No. JP 2002368238; T. Nagashima et al., “Carrier Recombination of Germanium Back-Contacted type bottom cells for three-terminal Tandem Solar Cells,” in Proceedings of the 17th European Photovoltaic Solar Energy Conference, 2001, Munich, Germany, pp. 2203-2206; S.-Y. Chiang et al., “Thin Tandem Junction Photovoltaic,” in Conference Record, 13th IEEE Photovoltaic Specialist Conference, 1978, New York, IEEE pp. 1290-1293; and T. Nagashima et al., “A germanium back-contact type cell for thermophotovoltaic applications,” in Proceedings of 3rd World Conference on Photovoltaic Energy Conversion, Vols. A-C, 2003, pp. 200-203.). In one design, a three-terminal tandem configuration includes a lower cell operable as a conventional rear-contacted two-terminal germanium cell, plus an additional contact for an upper cell or cells.

In some embodiments, the upper cell of the photovoltaic device can be configured as a monolithic integrated module structure (MIMS) (see International Patent Application Publication No. WO 03/100868; U.S. Pat. No. 4,341,918.; U.S. Pat. No. 6,239,354; A. I. Bennett et al., “An Integrated High- Voltage Solar Cell,” in Proceedings of the 6th Photovoltaic Specialist Conference, 1967, pp. 148-159; P. G. Borden, “A Monolithic series-connected AlGaAs/GaAs Solar Cell Array,” in Proceedings of the 14th Photovoltaic Specialist Conference, 1980, pp. 554-562; D. Krut et al., “Monolithic multi-cell GaAs laser power converter with very high current density,” in Conference Record of the Twenty-Ninth IEEE Photovoltaic Specialists Conference 2002, pp. 908-911; and S. van Riesen et al., “Fabrication of MIM-GaAs solar cells for high concentration PV,” in Proceedings of 3rd World Conference on Photovoltaic Energy Conversion, Vols. A-C, 2003, pp. 833-836). A MIMS arrangement can offer top-contacting for the upper cell, together with other advantages. MIMS has been developed for thermophotovoltaics with a view to reducing the current and increasing the voltage for a given high illumination level and hence reducing the impact of series resistance. The same advantage can result when a MIMS device is used for high concentrated sunlight. The lower part of the structure or substrate should be as pure as possible to reduce free carrier absorption and allow unabsorbed light from the cell to be reflected back to the source. However, the use of a pure or undoped substrate precludes the conventional use of the substrate as an electrical contact for the cell. Hence, all the contacts are provided on the top surface of the cell, which makes the configuration useful in the context of the present invention where the lower part of the upper cell is grown directly on the insulating layer and is hence not convenient for use as a contact surface.

A MIMS device comprises two or more individual photovoltaic subcells, each comprising a p-n junction formed from a region of n type material and a region of p-type material, such as the layered configuration of FIG. 1. The subcells may instead have a p-i-n junction structure with an intrinsic region that may or may not contain quantum wells. The individual subcells are formed as discrete entities (the junction regions are physically separated) adjacent to one another in or on a common substrate, and in a common plane substantially orthogonal to the incident illumination so that all the subcells are exposed to the illumination together. The subcells are electrically connected in series so that the individual contributions of the cells are added together. The use of a number of separate MIMS subcells gives an increased voltage and reduced current compared to a single cell of the same total illuminated area, which reduces ohmic losses. For subcells of equal size, a MIMS arrangement operates most efficiently if the device receives uniform illumination across its upper surface, so that each of the series-connected subcells generates the same current. Alternatively the subcells can be optimized for a non-uniform illumination such that each subcell is of differing size but generates the same current.

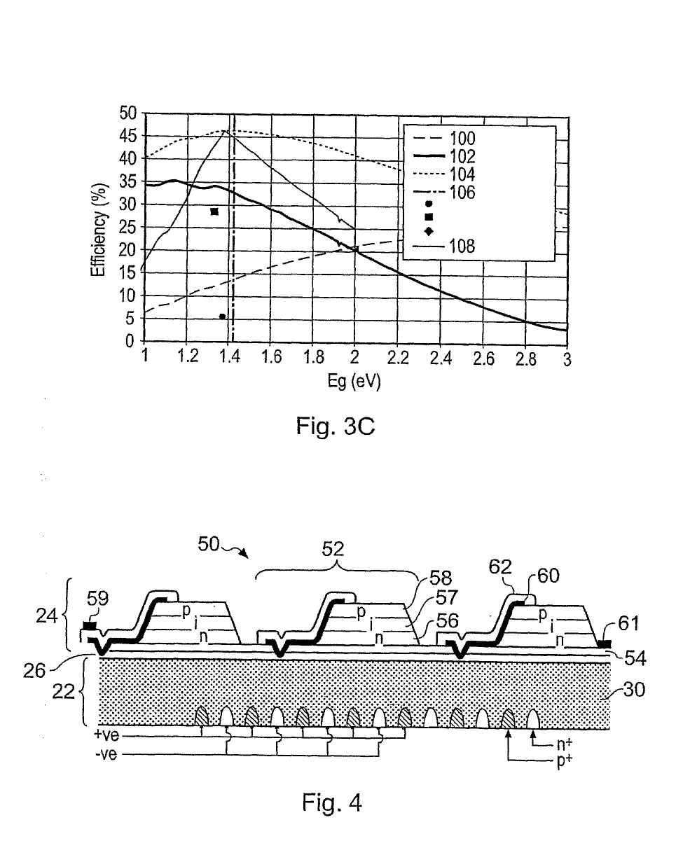

FIG. 4 shows a schematic representation of an embodiment of the invention in which the upper cell comprises several MIMS subcells. The device 50 comprises, as before, a lower cell 22 electrically isolated from an upper cell 24 by an insulating layer 26, where the insulating layer 26 and the upper cell 24 are monolithically grown on the lower cell 22. In this example, the lower cell comprises a rear-contacted cell with a plurality of alternate p-type and n-type surface regions formed in a substrate 30 as discussed with regard to FIG. 2, which are interconnected to give a positive terminal and a negative terminal. The upper cell 24 comprises three MIMS subcells 52. The subcells 52 are grown on a highly doped transverse conducting layer 54 which is itself grown on the insulating layer 26. Each subcell 52 comprises a p-n junction made up of a layer of n-type semiconductor 56 overlaying the transverse conducting layer 54 and a layer of p-type semiconductor 58 over the n-type layer 56, with an intermediate layer of intrinsic material 57 (which may be omitted depending on the preferred structure or which may or may not contain quantum wells). Each subcell 52 is physically separated from the adjacent cells. Grooves are formed in the transverse conducting layer 54 and an insulating layer 60 is added on the side of each subcell, bridging the p-n junction, and isolating the subcells electrically by forming a transverse conducting layer 54 for each cell. Conducting layers 62 are then added on top of the insulating layers 60 so as to connect the transverse conducting layer 54 of one subcell in series connection to the layer of opposite doping 58 at the top of the adjacent subcell. The top conducting layer 62 on the left-most subcell has a contact 59 and the transverse conducting layer 54 of the right most subcell has a contact 61 for extraction of current from the subcells 52. The electrical configuration for each subcell could be either p-i-n or (p-n) as in FIG. 4, or n-i-p (or n-p). The semiconductor material used for the subcells 52 has a greater bandgap than that used for the lower cell 22, with the materials of the transverse conducting layer 54 and the insulating layer 26 selected to allow unabsorbed photons to pass through to the lower cell 22.

The example of FIG. 4 is a particularly simple configuration; in reality the number of MIMS subcells is likely to be greater, with the subcells arranged in a one- or two-dimensional array parallel to the upper surface of the device. In other words, the subcells are arranged in the plane of the device and of the upper cell, where the plane is approximately normal to the expected propagation direction of incident light. The position, shape and quantity of subcells can be optimized to match the shape of the incident illuminating spot, which will generally be focused or otherwise concentrated. Further, the arrangement of the p-type and n-type regions within each subcell may be different from that shown in FIG. 4; any arrangement that gives an operable junction but which allows physical separation together with electrical series connection of the subcells may be used.

In other embodiments, the upper cell 24 may comprise a conventional tandem cell, in which two or more p-n junctions (individual subcells) of increasing bandgap are grown on top of each other together with tunnel junctions to connect the subcells in electrical series (see International Patent Application Publication No. WO 03/100868). Despite the various disadvantages of tandem cells (such as current constraints), such a configuration may offer increased efficiency compared with a regular tandem cell, or with a device of the present invention with a single junction upper cell. Further, the spectral range of the tandem cell arrangement is extended by the electrically isolated lower cell. To allow operation of the lower cell, each photovoltaic subcell of the upper tandem cell should be fabricated from semiconductor material having a larger bandwidth than that of the material of the lower cell.

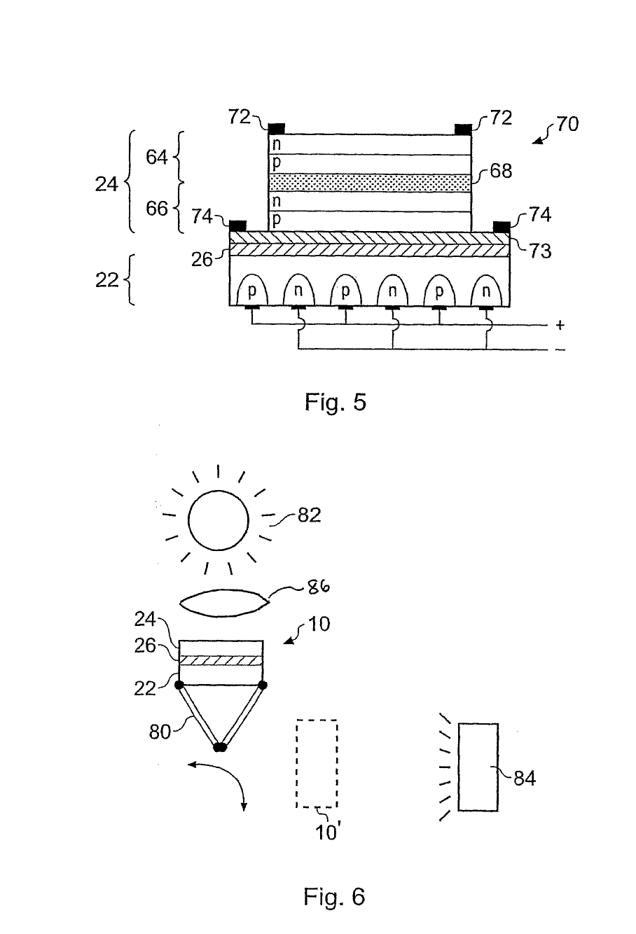

FIG. 5 shows a schematic representation of a device in which the upper cell has the form of a tandem cell comprising two subcells. The device 70 comprises, as before, an upper cell 24 and a lower cell 22 separated by an insulating layer 26 and provided with independent electrical connections. The lower cell 22 has the junction structure previously described with respect to FIG. 2. The upper cell comprises an upper subcell or p-n junction region 64 and a lower subcell or p-n junction region 66. Between the two junctions 64, 66 is a tunnel junction 68 that allows current flow between the two junctions and hence connects the two junctions in electrical series. Electrical connectivity for extracting the common current from the upper cell 24 as a whole is provided by electrical contacts 72 on the top surface of the upper subcell 64, and further electrical contacts 74 provided at the edges of an epitaxially grown high doped transverse conducting layer 73 grown underneath but protruding beyond the lower subcell 66. The upper subcell has a larger bandgap than the lower subcell which has a larger bandgap than the lower cell, so that unabsorbed incident photons pass down through the device until they reach a junction with an appropriate bandgap. The electrical configuration for the subcells may be n-p as shown (or n-i-p) or alternatively p-n (or p-i-n). The i-regions may or may not contain quantum wells.

The tandem option for the upper cell can be combined with the MIMS configuration by growth of a tandem cell as in FIG. 5 followed by fabricating the tandem cell into MIMS subcells.

Other features of the upper and lower cells are also contemplated. For example, the upper cell (or subcells) may include one or more Bragg reflectors and/or photonic cavity structures to enhance photon recycling in the upper cell, giving enhanced absorption. The lower cell may be treated by passivation, which is a surface treatment that reduces the incidence of recombination of photo-generated carriers in the vicinity of the surface (see W. P. Mulligan et al., “Development of chip-size silicon solar cells,” in Conference Record of the Twenty-Eighth IEEE Photovoltaic Specialists Conference—2000, IEEE Photovoltaic Specialists Conference, 2000, pp. 158-163), or by doping to form a minority carrier mirror to reduce photon losses. These approaches also aim to give increased photon absorption, and hence increased conversion efficiency.

Photovoltaic devices according to the present invention are suitable for a wide range of electricity generating applications, in part because the spectral range can be both relatively broad and specifically tailored to given photon sources by selecting appropriate materials for the various cells. In particular, the devices can be tailored for operation with a solar spectrum or a thermophotovoltaic spectrum (see V. M. Andreev et al., “Thermophotovoltaic Cells With Sub-Bandgap Photon Recirculation”, in Proceedings of the 17th European Photovoltaic Solar Energy Conference, 2001, Munich, Germany, pp. 219-222) in which the photons are produced by a heat source, so that the device can be used in a hybrid solar/thermophotovoltaic mode, in which the device is exposed to solar illumination during daylight hours and illumination from a thermal source during the hours of darkness. One of the upper cell or the lower cell can be designed for efficient conversion of solar photons, which are dominated by visible wavelengths, and the other for efficient conversion of thermal photons, which are dominated by infrared wavelengths. The upper cell can be selected as the solar cell and the lower cell as the thermal cell; the respective effective bandgaps will make the upper cell effectively transparent to the longer wavelength thermal photons which will thus pass through to the lower cell, and the upper surface of the device can receive both the solar and thermal photons. In solar operation, although the upper cell is likely to generate much of the electricity, the bottom cell will also generate a significant amount. In thermophotovoltaic mode it is likely that the majority of the electricity will be generated in the lower cell. The device can be mounted in a movable manner, such as on a pivot, so that the device can be moved from an optimum position for receiving sunlight to an optimum position for receiving photons from a suitably positioned thermal source. The sunlight position will typically be a variable position for tracking the sun during the course of the day. Any suitable positioning mechanism for moving the device between positions may be employed; the choice may depend on factors such as size, cost, and the relative locations of the sun and the thermal source. Alternatively, the thermal source may be moved into and out of a position for supplying thermal photons to the device, possibly together with movement of the device. In a further alternative, arrangements, including movable arrangements, of lenses, mirrors and/or optical fibers can be employed to direct the relevant radiation (solar or thermal) from its source to the appropriate part of the device. In general, any positioning apparatus can be employed that is operable to configure a system comprising the device, the thermal source and any lenses, etc. that are used between a configuration in which the device is arranged to receive solar photons and a configuration in which the device is arranged to receive thermal photons.

Hybrid operation of this kind, where each cell dominates the device function at different times, is not possible in a conventional series-connected tandem cell since these require equal current to be generated in each cell at all times for efficient operation.

FIG. 6 shows a simplified schematic representation of a system for using a device of the invention in this hybrid mode. The device 10 comprises an upper cell 24 optimized for conversion of photons from the sun 82, and a lower cell 22 optimized for conversion of longer-wavelength photons from a thermal source 84 located near the device 10 but not between the device 10 and sun 84. In accordance with the invention, an insulating layer 26 separates the two cells. The device 10 is mounted on a pivot system 80 operable to move the device 10 from a first position (as illustrated in the FIGURE) where the top surface of the device is exposed to the sun, to a second position 10′ (shown in phantom in the FIGURE) where the top surface is exposed to the thermal source 84. The FIGURE is highly simplified, and with the exception of a representative lens 86 (photon collection assembly) to collect photons from the sun and focus them onto the device 10, does not show components such as the electrical contacts for the upper and lower cells, circuitry to which these will be connected, lenses and other optical couplers for concentrating and directing photons onto the device, a motor or similar for moving the device, or a heat sink.

This hybrid operation, where the invention provides a system in which the photovoltaic device is illuminated by two different optical sources giving photons at different wavelengths, is not limited to a solar/thermal combination. Alternative systems for use in solar power generation may employ other optical sources as a local photon source in place of the thermal source. A thermal source is one which produces radiation (photons) whose intensity and spectral distribution depend on the temperature of the source and on the material from which the source is made. This may be replaced by any other radiation source to provide photons to supplement the solar photons, where this source can supply photons in a wavelength range that can be converted by one or other of the cells in the photovoltaic device, as determined by the bandgaps of these cells. Examples of local photon sources include sources of substantially monochromatic radiation, such as lasers and light-emitting diodes, and luminescent sources, which typically provide narrow-band radiation by the radiative de-excitation of materials such as phosphors, organic dyes, semiconductor crystals and nanoparticles. An advantage of a narrow-band or monochromatic source is that the wavelength range of the emitted photons can be matched closely to the bandgap of the associated photovoltaic cell so that the majority of the photons can be absorbed. Broad-band or white light sources may be used instead, though.

Thus, the hybrid system includes a monolithic photovoltaic device having two electrically isolated cells with different effective bandgaps that is provided with two associated photon sources of different output wavelength range, one each to provide photons that can be converted in at least one of the two cells. For a solar system having a supplementary local photon source to provide photons during the night, one of the photon sources is the local source, which may take any suitable form as discussed above. The other photon source is effectively the sun, but in order to supply the solar photons to the photovoltaic device in an efficient manner, the system should further include some arrangement of lenses, mirrors, optical fibers, light pipes, waveguides and the like to collect the solar radiation and direct and focus it onto the appropriate part of the device. This solar photon collection assembly can be thought of as a photon source. Hence the system has two photon sources, one associated with each cell according to wavelength and bandgap.

Further, the supply of photons from the sun may a direct supply of substantially the full solar spectrum, or may be the supply of photons from a modified solar spectrum, where the solar output has been attenuated, truncated or otherwise altered in some way before being passed to the photovoltaic device.

Also, the system may be full solar system, in which both the photon sources supply photons derived from the solar spectrum. Hence each photon source can be a solar photon collection assembly delivering a full or modified solar spectrum.

However, the device is not limited to systems for solar power generation. Instead of the sun/photon collecting assembly of the previous embodiments, the system may instead comprise a further local photon source. Each local photon source supplies photons with a wavelength range matched for efficient conversion in one or other of the cells in the device, according to bandgap. The two local sources may be of the same type operating at different wavelengths, such as two lasers with different output wavelengths, or may be of two different types, according to any combination of suitable local photon sources. The local sources can be selected to provide good spectral matches with the bandgaps of the semiconductor materials from which the cells are made, perhaps to exploit particularly efficient photovoltaic materials, for example.

As with the solar system, a system with two local sources can operate in an alternate mode, in which the sources are operated at different times. Alternatively, the sources may be operated at the same time, so that both provide photons to the photovoltaic device simultaneously. A further alternative is a supplementary mode, in which one of the sources provides most of the photons, and the other source can be switched on in addition if there is a temporary increase in the demand for electrical power from the system.

In a system where the two sources are intended to be operated at different times, the system may include a movement or position configuring assembly as discussed with regard to the solar system, to configure the components between a first position in which the upper cell receives photons from the first local source, which propagate through to the lower cell, and a second position in which the upper cell receives photons from the second local source, which are absorbed in the upper cell.

FIG. 7 shows a simplified representation of an example of such a system, in which the device 10 is movable on a pivot system 80 between a first position in which the upper cell 24 is adjacent to a first local photon source 88 and a second position (shown in phantom as 10′) in which the upper cell 24 is adjacent to a second local photon source 90. Again, no lenses, electrical connections, heat sinks, etc. are shown.

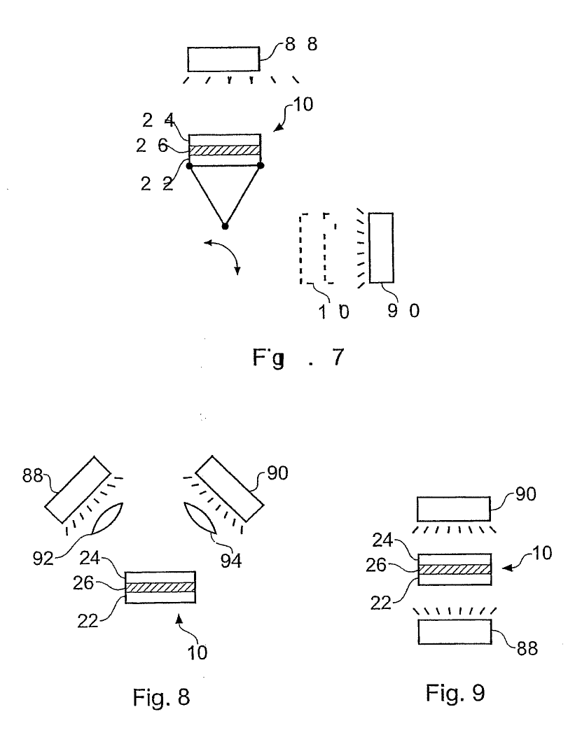

Alternatively, the system may be arranged for simultaneous illumination of the upper cell by both local sources. FIG. 8 shows a simplified representation of an example of such an arrangement. The device 10 may remain fixed relative to each photon source 88, 90, and each photon source may have an assembly 92, 94 of lenses, mirrors, etc configured to direct light emitted from that source onto the upper cell 24 of the device 10. A fixed configuration of this type is simpler to implement for two local sources than for a solar and local source system, because there is no requirement for one of the lens assembly to track the position of the sun throughout the day. The system of FIG. 8 can be used for simultaneous or alternate supply of photons from the two sources.

FIG. 9 shows a simplified representation of a further example system suitable for use with both simultaneous and alternative illumination. In this case, the two photon sources 88, 90 are positioned to each supply photons directly to their associated cell 22, 24. As with FIG. 8, this does not require any moving parts, and further does not require the insulating layer 26 to be transparent to the photons from the first photon source 88 that are intended for the lower cell 22. However, it does require that both cells 22, 24 have a surface suitable for receiving incident photons for absorption. The arrangement of FIG. 9 may also be adopted for a solar system in which a solar photon collecting assembly forms one of the photon sources.

In all examples, one or both of the photovoltaic cells may be a semiconductor cell with a conventional bandgap. Alternatively, one or both cells may be a quantum well cell, in which bandgaps are more commonly thought of in terms of an effective bandgap, an absorption edge or a band edge. For the purposes of understanding and implementing the present invention, these various terms should be understood to carry the same meaning, and are hence used interchangeably in the present specification.

Further, each of the first photon source and the second photon source may be replaced with two or more photon sources that operate in conjunction to supply the photons in the first and second wavelength ranges associated with the first and second bandgaps. This option may be used to achieve a particular photon spectrum to match one or other of the bandgaps, or to achieve a desired optical power level, for example.

What is claimed is:

1. A photovoltaic system comprising:
(a) a photovoltaic device comprising:
a lower photovoltaic cell fabricated from semiconductor material having a first bandgap and having first electrical contacts for extraction of current from the lower cell;
an electrically insulating layer monolithically fabricated on the lower photovoltaic cell; and
an upper photovoltaic cell monolithically fabricated on the electrically insulating layer from semiconductor material having a second bandgap larger than the first bandgap and having second electrical contacts for extraction of current from the upper cell;
(b) one or more first photon sources operable to supply photons to the photovoltaic device, the photons having wavelengths in a first wavelength range associated primarily with the first bandgap; and
(c) one or more second photon sources operable to supply photons to the photovoltaic device, the photons having wavelengths in a second wavelength range primarily associated with the second bandgap.

2. The photovoltaic system of claim 1, wherein one of the first and second photon sources is a photon collecting assembly arranged to collect photons from the sun or a modified solar spectrum and deliver them to the photovoltaic device, and the other of the first and second photon sources is a local photon source.

3. The photovoltaic system of claim 2, wherein the local photon source is a thermal photon source, a monochromatic photon source, or a luminescent photon source.

4. The photovoltaic system of claim 2, wherein the second photon source is the photon collecting assembly, and the upper photovoltaic cell is optimized for photovoltaic conversion of photons emitted by the sun or a modified solar spectrum.

5. The photovoltaic system of claim 4, wherein the lower photovoltaic cell is optimized for photovoltaic conversion of photons emitted by the local photon source.

6. The photovoltaic system of claim 1, wherein the first photon source is a local photon source, and the second photon source is also a local photon source.

7. The photovoltaic system of claim 6, wherein one or both local photon sources is a thermal photon source, a monochromatic photon source or a luminescent photon source.

8. The photovoltaic system of claim 1, wherein the first photon source is a photon collecting assembly arranged to collect photons from the sun or a modified solar spectrum and deliver them to the photovoltaic device, and the second photon source is a photon collecting assembly arranged to collect photons from the sun or a modified solar spectrum and deliver them to the photovoltaic device.

9. The photovoltaic system of claim 1, wherein the first photon source and the second photon source are a common local photon source operable to supply photons in the first wavelength range and the second wavelength range.

10. The photovoltaic system of claim 1, wherein the photons from the first photon source are supplied to the lower photovoltaic cell via the upper photovoltaic cell and the insulating layer, and the photons from the second photon source are supplied directly to the upper photovoltaic cell.

11. The photovoltaic system of claim 10, further comprising a positioning mechanism operable to configure the photovoltaic system between a first configuration in which the upper photovoltaic cell can receive photons supplied by the first photon source, and a second configuration in which the upper photovoltaic cell is exposed to photons supplied by the second photon source.

12. The photovoltaic system of claim 1, wherein the photons from the first photon source are supplied directly to the lower photovoltaic cell, and the photons from the second photon source are supplied directly to the upper photovoltaic cell.

13. The photovoltaic system of claim 1, wherein the lower photovoltaic cell is fabricated from an indirect bandgap semiconductor material.

14. The photovoltaic system of claim 13, wherein the indirect bandgap semiconductor material is silicon, germanium, or silicon-germanium alloys.

15. The photovoltaic system of claim 1, wherein the first electrical contacts are located on a lower side of the lower photovoltaic cell, opposite the electrically insulating layer.

16. The photovoltaic system of claim 1, wherein the electrically insulating layer has a bandgap that is larger than the bandgap of the semiconductor material from which the upper cell is fabricated.

17. The photovoltaic system of claim 1, wherein the upper photovoltaic cell comprises two or more photovoltaic subcells electrically connected in series and arranged adjacent to one another in the plane of the upper cell to form a monolithic integrated module structure (MIMS).

18. The photovoltaic system of claim 17, wherein each photovoltaic subcell comprises two or more p-n junction structures arranged one above another and fabricated from semiconductor materials of different bandgap, and electrically connected in series by one or more tunnel junctions to form a tandem photovoltaic subcell.

19. The photovoltaic system of claim 1, wherein the upper photovoltaic cell comprises two or more p-n junction structures arranged one above another and fabricated from semiconductor materials of different bandgap, and electrically connected in series by one or more tunnel junctions to form a tandem photovoltaic cell.

20. The photovoltaic system of claim 1, wherein the upper photovoltaic cell comprises one or more Bragg reflectors and/or photonic cavity structures to increase photon recycling in the upper photovoltaic cell.

21. The photovoltaic system of claim 1, wherein one or more surfaces of the lower cell are passivated to reduce surface recombination of charge carriers.

22. The photovoltaic system of claim 1, wherein the first electrical contacts comprise a first single pair of electrical contacts, and the second electrical contacts comprise a second single pair of electrical contacts.

23. A method of generating electricity via the photovoltaic effect comprising:
(a) providing a photovoltaic device comprising:
a lower photovoltaic cell fabricated from semiconductor material having a first bandgap and having first electrical contacts for extraction of current from the lower cell;
an electrically insulating layer monolithically fabricated on the lower photovoltaic cell; and
an upper photovoltaic cell monolithically fabricated on the electrically insulating layer from semiconductor material having a second bandgap larger than the first bandgap and having second electrical contacts for extraction of current from the upper cell;
(b) exposing the device to photons supplied by one or more first photon sources, the photons having wavelengths in a first wavelength range associated primarily with the first bandgap, and extracting current from at least the lower photovoltaic cell; and
(c) exposing the device to photons supplied by one or more second photon sources, the photons having wavelengths in a second wavelength range associated primarily with the second bandgap, and extracting current from at least the upper photovoltaic cell.

24. The method of claim 23, wherein one of the first and second photon sources is the sun or a modified solar spectrum and the other of the first and second photon sources is a local photon source.

25. The method of claim 24, wherein the local photon source is a thermal photon source, a monochromatic photon source or a luminescent photon source.

26. The method of claim 24, wherein the second photon source is the sun or a modified solar spectrum, and the upper photovoltaic cell is optimized for photovoltaic conversion of photons emitted by the sun or the modified solar spectrum.

27. The method of claim 24, further comprising exposing the device to photons supplied by the sun during daylight hours, and exposing the device to photons supplied by the local photon source outside daylight hours.

28. The method of claim 23, wherein the first photon source is a local photon source, and the second photon source is also a local photon source.

29. The method of claim 28, wherein one or both local photon sources is a thermal photon source, a monochromatic photon source or a luminescent photon source.

30. The method of claim 28, further comprising exposing the device to photons supplied by the first photon source during one or more first time periods, and exposing the device to photons supplied by the second photon source during one or more second time periods different from the one or more first time periods.

31. The method of claim 28, further comprising exposing the device to photons supplied by the first photon source simultaneously with exposing the device to photons supplied by the second photon source.

32. The method of claim 23, wherein the first photon source is a photon collecting assembly arranged to collect photons from the sun or a modified solar spectrum and deliver them to the photovoltaic device, and the second photon source is a photon collecting assembly arranged to collect photons from the sun or a modified solar spectrum and deliver them to the photovoltaic device.

33. The method of claim 23, wherein the first photon source and the “5 second photon source are a common local photon source operable to supply photons in the first wavelength range and the second wavelength range.

34. The method of claim 23, wherein exposing the device to photons supplied by the first photon source and exposing the device to 0 photons supplied by the second photon source each comprise exposing the upper photovoltaic cell to the photons.

35. The method of claim 34, wherein exposing the device to photons supplied by the first photon source comprises arranging the device in a first 5 configuration in which the upper photovoltaic cell is exposed to photons from the first photon source, and exposing the device to photons supplied by the second photon source comprises arranging the device in a second configuration in which the upper photovoltaic cell is exposed to photons from the second photon source.

36. The method of claim 23, wherein exposing the device to photons supplied by a first photon source comprises exposing the lower photovoltaic cell to photons from the first photon source, and exposing the device to photons supplied by a second photon source comprises exposing the upper photovoltaic cell to photons from the second photon source.
